(19) United States
(12) Patent Application Publication
(10) Pub. No.: US 2012/0178263 A1
(43) Pub. Date: Jul. 12, 2012

(54) SUBSTRATE PROCESSING APPARATUS

(75) Inventors: Shigeki TOZAWA, Nirasaki-shi (JP); Yusuke Muraki, Nirasaki-shi (JP); Tadashi Ilno, Koshi-shi (JP); Daisuke Hayashi, Nirasaki-shi (JP)

(73) Assignee: Tokyo Electron Limited, Tokyo-To (JP)

(21) Appl. No.: 13/423,722

(22) Filed: Mar. 19, 2012

Related U.S. Application Data
(63) Continuation of application No. 12/086,634, filed on Jun. 17, 2008, now abandoned.

(30) Foreign Application Priority Data
Dec. 22, 2005 (JP) 2005-369754

(51) Int. Cl. H01L 21/31

(52) U.S. Cl. 438/743; 257/E21.24

(57) ABSTRACT

[Problem] To provide a substrate processing apparatus capable of preventing adherence of hydrogen fluoride to an inner surface the like of a chamber.

[Means for Solving] An apparatus housing and processing a substrate W in a chamber includes a hydrogen fluoride gas supply path 61 for supplying a hydrogen fluoride gas into a chamber 40, wherein a part or whole of an inner surface of the chamber 40 is formed of Al or Al alloy which has not been subjected to surface oxidation treatment. The chamber 40 includes a lid 52 closing an upper opening of a chamber main body 51, and at least an inner surface of the lid 52 is formed of the Al or Al alloy which has not been subjected to alumite treatment.

### TECHNICAL FIELD

The present invention relates to a substrate processing apparatus.

### BACKGROUND ART

In a process of manufacturing a semiconductor device, for example, there is known processing of removing an oxide film (silicon dioxide (SiO₂)) existing on the surface of the semiconductor wafer (hereinafter, referred to as a “wafer”) (see Patent Documents 1, 2, and 3). This processing is to bring the inside of a chamber in which the wafer is housed into a reduced-pressure state close to a vacuum state, supply a mixed gas of hydrogen fluoride gas (HF) and ammonia gas (NH₃) into the chamber while temperature-regulating the wafer to a predetermined temperature to change an oxide film to a reaction product, and then heat and vaporize (sublimate) the reaction product to thereby remove it from the wafer.

Usually, the chamber of the substrate processing apparatus performing such processing is formed of Al (aluminum), and the inner surface of the chamber is subjected to surface oxidation treatment. More specifically, the surface of the chamber is forcibly oxidized to form an oxide coating (a coating (Anodized aluminum) of aluminum oxide (alumina (Al₂O₃))) to cover the inner surface of the chamber by the oxide coating to thereby improve the hardness, the corrosion resistance, and the durability of the inner surface to protect Al constituting the chamber from corrosion and the like.
[Patent Document 1] US Patent Application No. 2004/0182417
[Patent Document 2] US Patent Application No. 2004/0184792
[Patent Document 3] Japanese Patent Application Laid-open No. 2005-39185

### DISCLOSURE OF THE INVENTION

### Problems to be Solved by the Invention

However, a conventional substrate processing apparatus has a problem of hydrogen fluoride gas liquefying and staying adhering to the inner surface of the chamber and the like. Hence, there has been a phenomenon that hydrogen fluoride is adsorbed to the inner surface and the like to decrease the concentration and pressure of hydrogen fluoride in the chamber, and conversely hydrogen fluoride is released from the inner surface of the chamber and the like to increase the concentration and pressure of hydrogen fluoride. In this case, the concentration and pressure of hydrogen fluoride in the chamber cannot be stabilized to target values, causing occurrence of processing unevenness of the wafer.

Further, hydrogen fluoride has a strong corrosion property and is harmful also to human body, and therefore needs to be prevented from leaking to the outside of the chamber. Therefore, it is necessary to forcibly exhaust the chamber and thoroughly collect hydrogen fluoride from the inside of the chamber after completion of the processing of the wafer, but there is a problem of components of hydrogen fluoride, if adhering to the inner surface of the chamber and the like, staying in the chamber. To exhaust the adhering hydrogen fluoride from the chamber, forced exhaust needs to be performed for a long time, leading to inefficiency.

The present invention has been developed in consideration of the above viewpoints and has an object to provide a substrate processing apparatus capable of preventing adherence of hydrogen fluoride to the inner surface of a chamber and the like.

### Means for Solving the Problems

To solve the above problem, the present invention provides an apparatus housing and processing a substrate in a chamber, the substrate processing apparatus including: a hydrogen fluoride gas supply path for supplying a hydrogen fluoride gas into the chamber, wherein a part or whole of an inner surface of the chamber is formed of Al or Al alloy which has not been subjected to surface oxidation treatment.

The chamber may include a chamber main body and a lid closing an upper opening of the chamber main body; and at least an inner surface of the lid may be formed of the Al or Al alloy which has not been subjected to surface oxidation treatment. Further, a transfer port for transferring the substrate into/out of the chamber and an opening/closing mechanism for opening/closing the transfer port may be provided, and an inner surface of the opening/closing mechanism facing an inside of the chamber may be formed of the Al or Al alloy which has not been subjected to surface oxidation treatment. Further, a surface roughness Ra of a portion formed of the Al or Al alloy may be 6.4 μm or less. More preferably, a surface roughness Ra of a portion formed of the Al or Al alloy may be 1 μm or less.

An ammonia gas supply path for supplying an ammonia gas into the chamber may be provided. An exhaust path for forcibly exhausting the chamber may be provided.

Processing performed in the chamber may be to change silicon dioxide existing on a surface of the substrate into a reaction product capable of vaporizing by heating. The processing of changing silicon dioxide existing on a surface of the substrate into a reaction product here is, for example, COR (Chemical Oxide Removal) processing. The COR processing produces a reaction product by supplying a gas containing halogen element and a basic gas as a processing gas to the substrate to cause an oxide film on the substrate to chemically react with gas molecules in the processing gas. The gas containing halogen element is, for example, hydrogen fluoride gas (HF) and the basic gas is, for example, ammonia gas (NH₃), and in this case, a reaction product is produced which mainly contains ammonium fluosilicate ((NH₄)2SiF₆ and water (H₂O).

### Effect of the Invention

According to the present invention, hydrogen fluoride can be prevented from staying adhering in the chamber. The concentration and pressure of hydrogen fluoride in the chamber can be stabilized to target values. The occurrence of processing unevenness of the wafer can be prevented. The hydrogen fluoride in the chamber can be quickly exhausted.

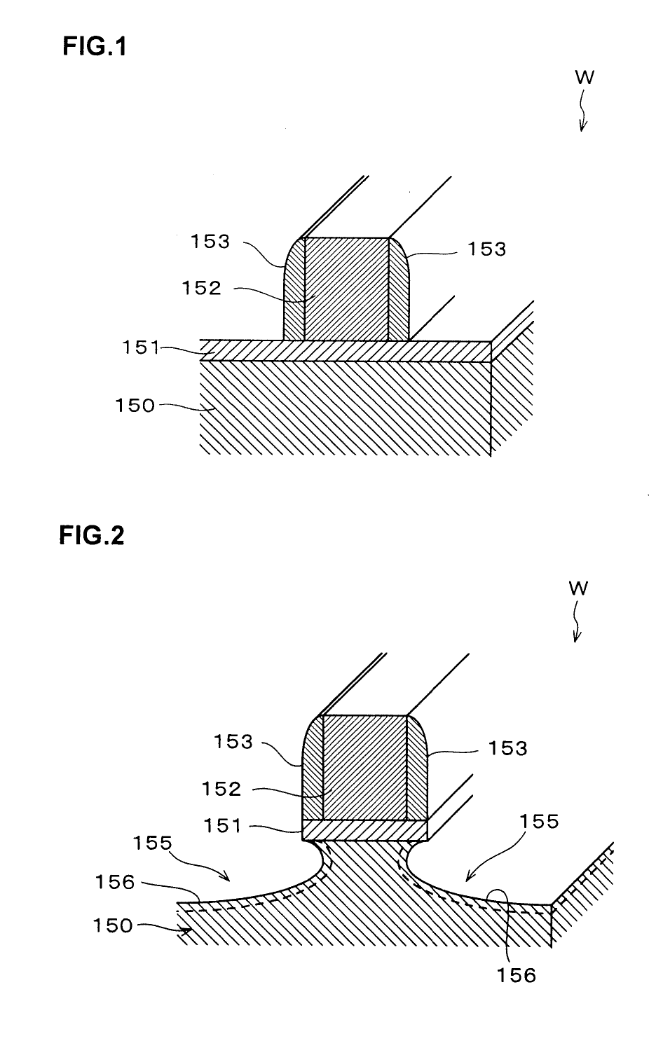

### BRIEF DESCRIPTION OF THE DRAWINGS

[FIG. 1]

A schematic longitudinal sectional view showing a structure of a front surface of a wafer before a Si layer is subjected to etching treatment.

[FIG. 2]

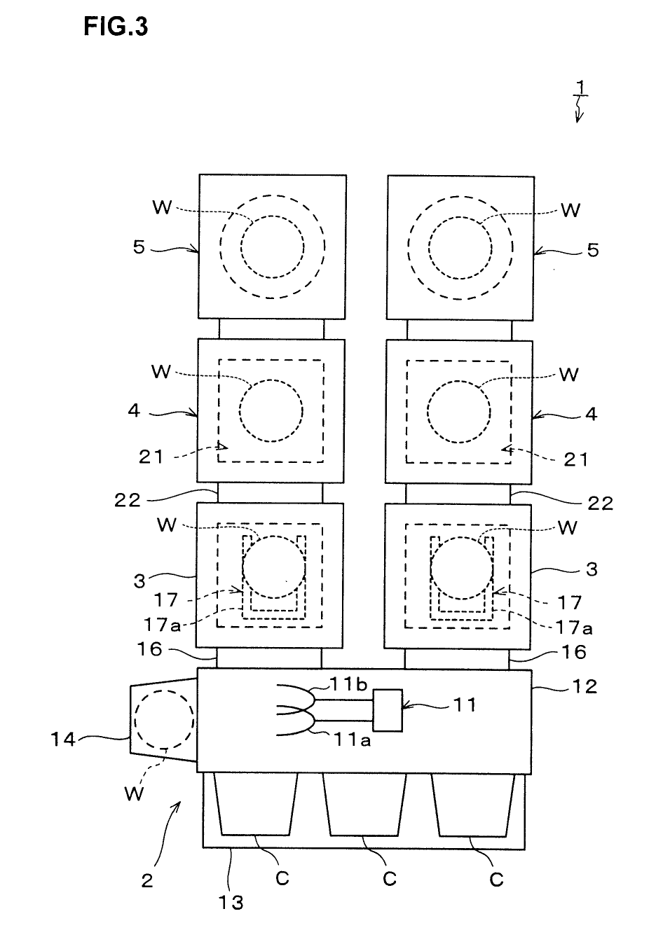

A schematic longitudinal sectional view showing the structure of the front surface of the wafer after the Si layer is subjected to etching treatment.

[FIG. 3]

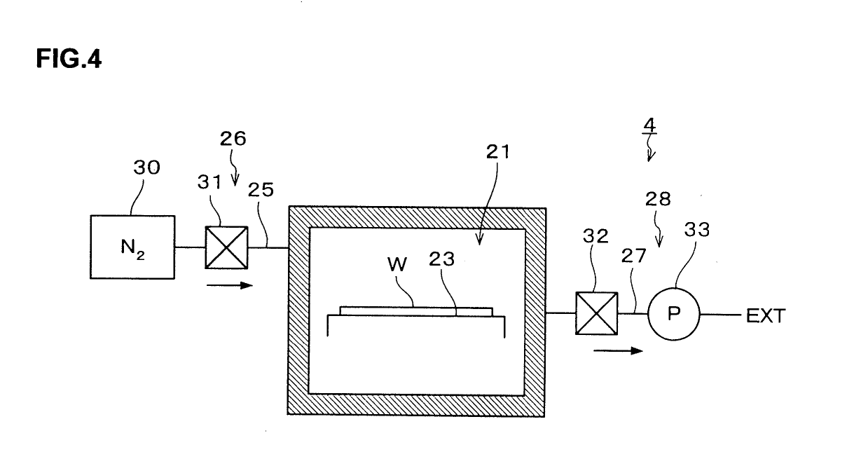

A schematic plan view of a processing system.

[FIG. 4]

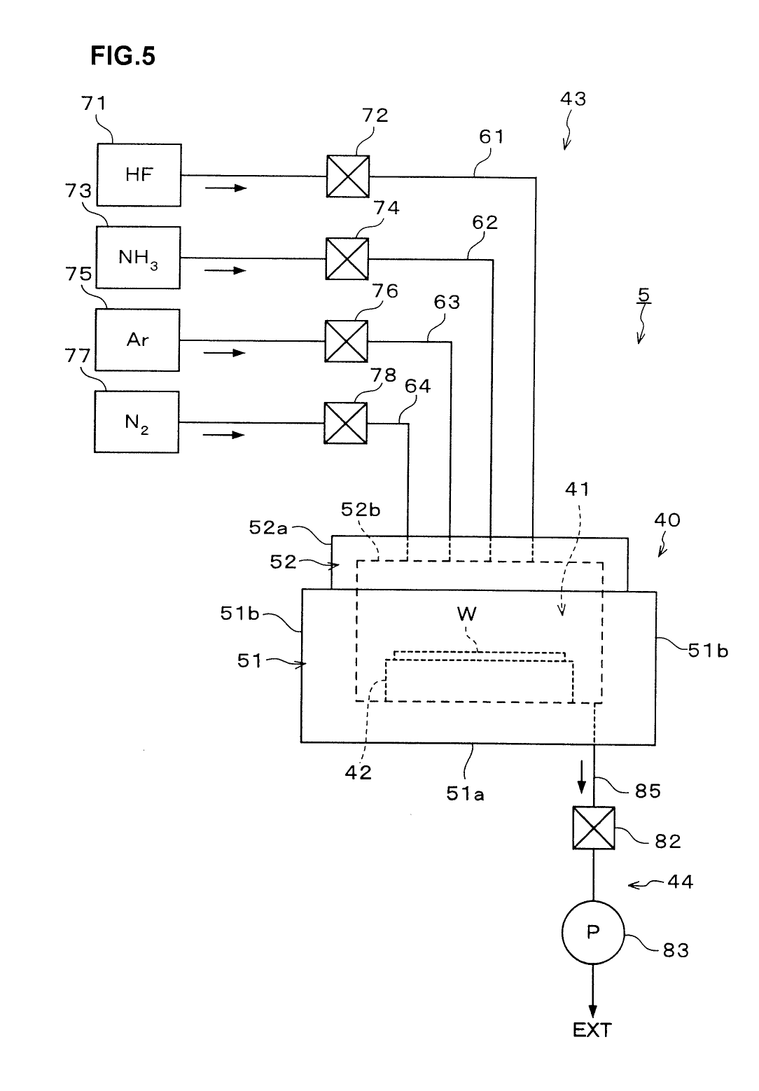

A schematic longitudinal sectional view showing a configuration of a PHT processing unit.

[FIG. 5]

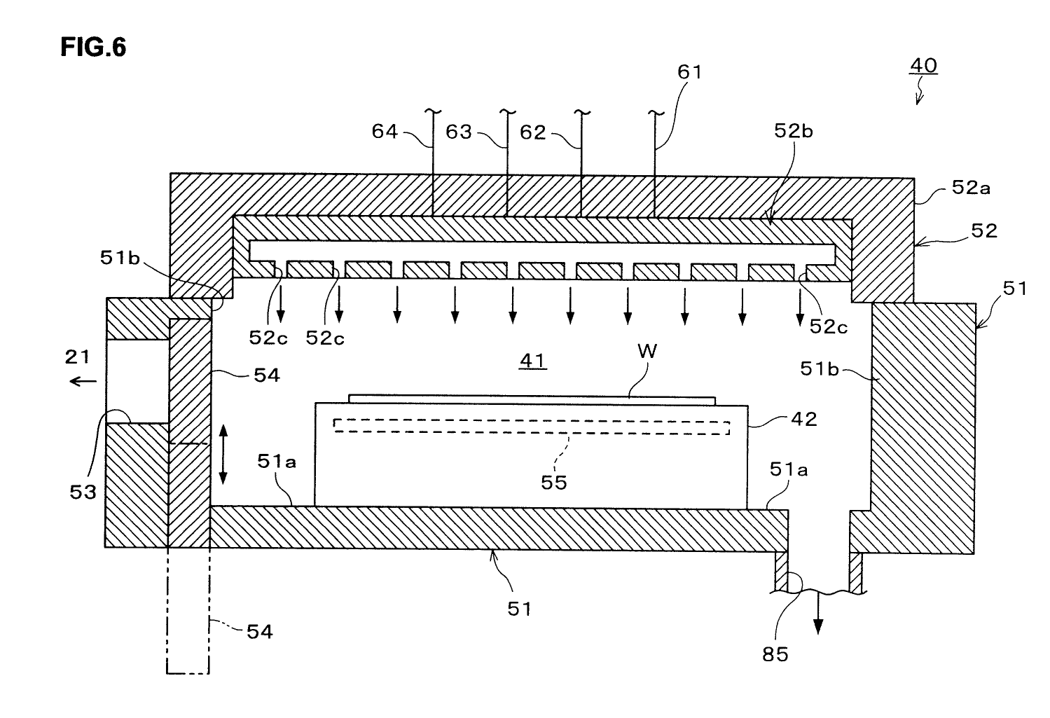

An explanatory view showing a configuration of a COR processing unit.

[FIG. 6]

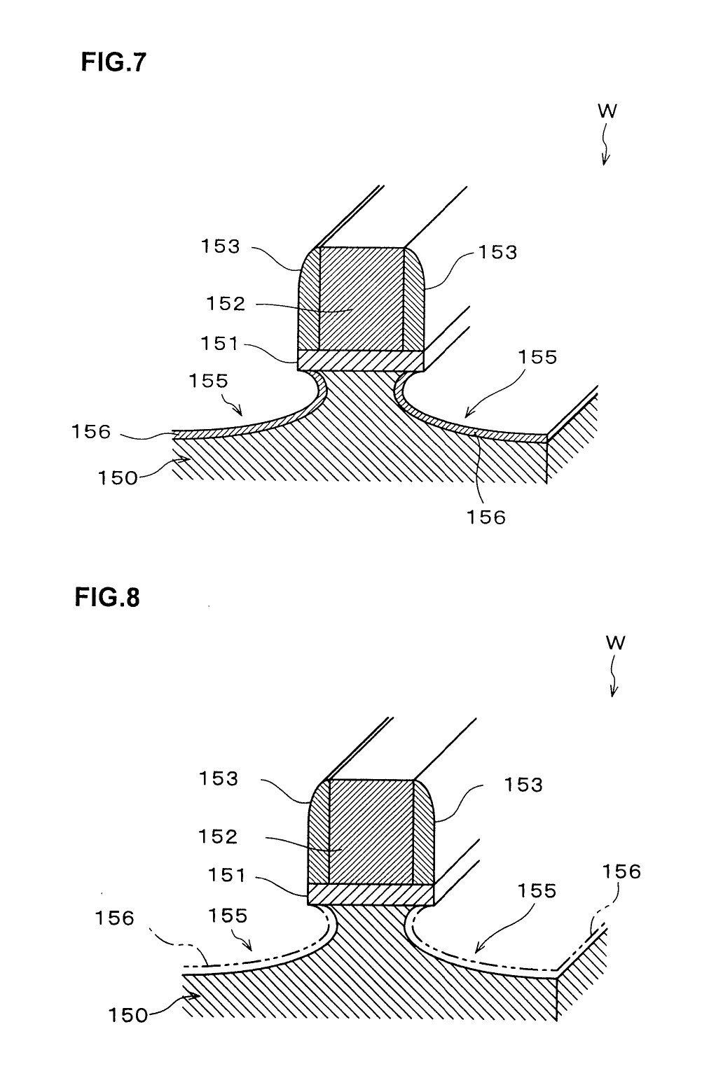

A schematic longitudinal sectional view showing a configuration of a chamber of the COR processing unit.

[FIG. 7]

A schematic longitudinal sectional view a state of the front surface of the wafer after COR processing.

[FIG. 8]

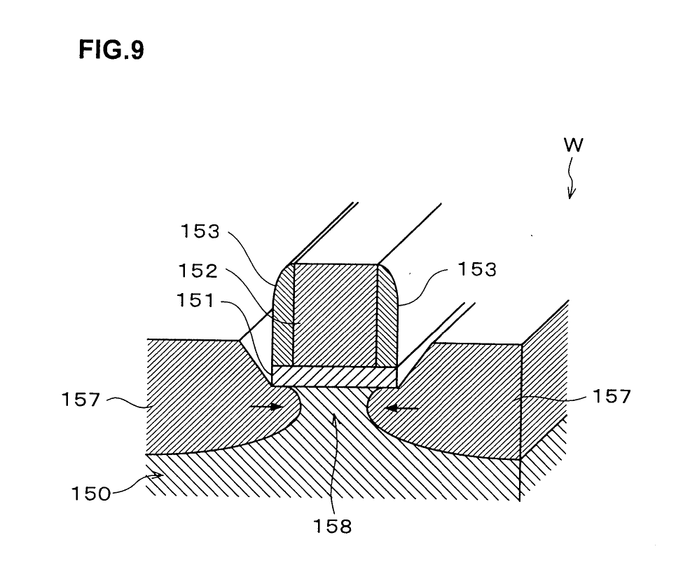

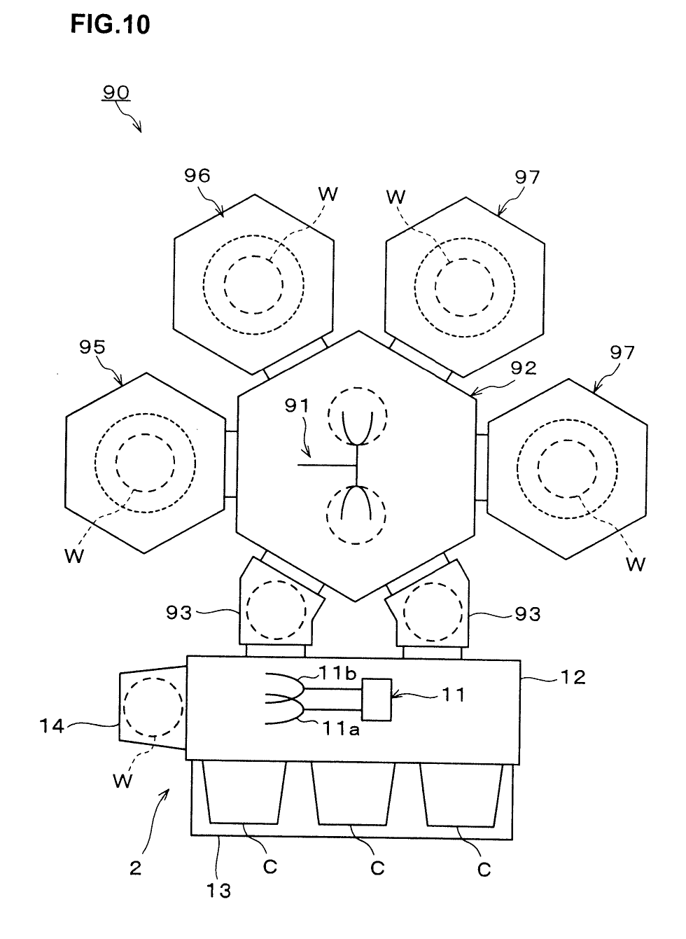

A schematic longitudinal sectional view showing a state of the front surface of the wafer after PHT processing.

[FIG. 9]

A schematic longitudinal sectional view showing a state of the front surface of the wafer after SiGe layer deposition processing.

[FIG. 10]

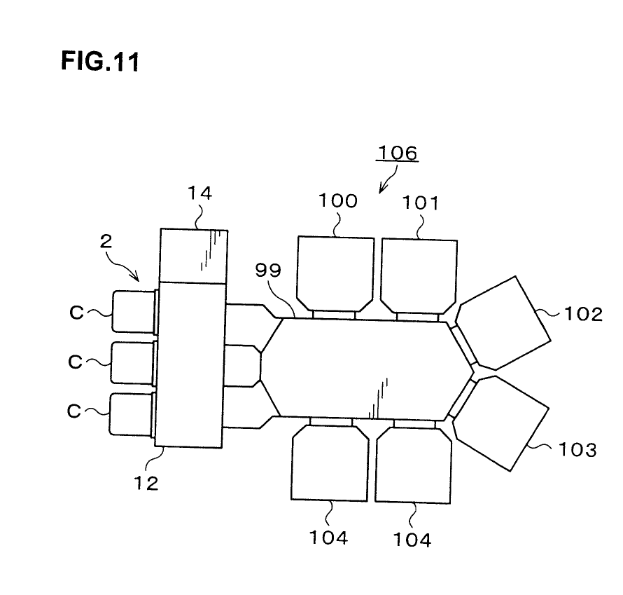

A schematic plan view of a processing system according to another embodiment.

[FIG. 11]

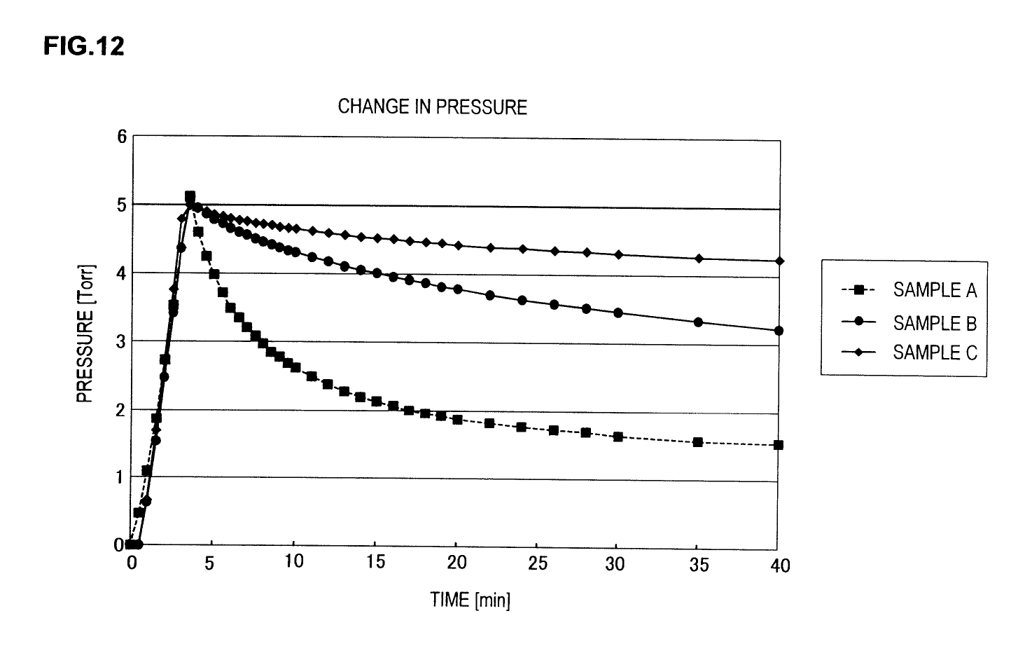

An explanatory view of a processing system in which six processing units are provided around a common transfer chamber.

[FIG. 12]

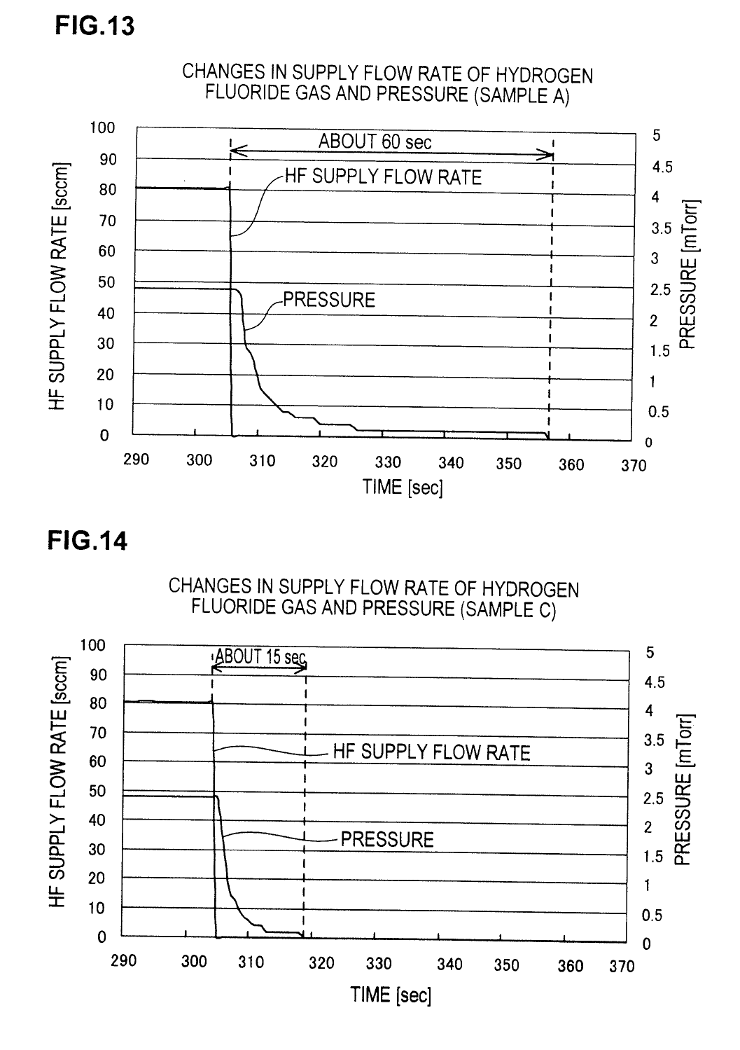

A graph showing experimental results of Experiment 1.

[FIG. 13]

A graph showing experimental results regarding Sample A of Experiment 2.

[FIG. 14]

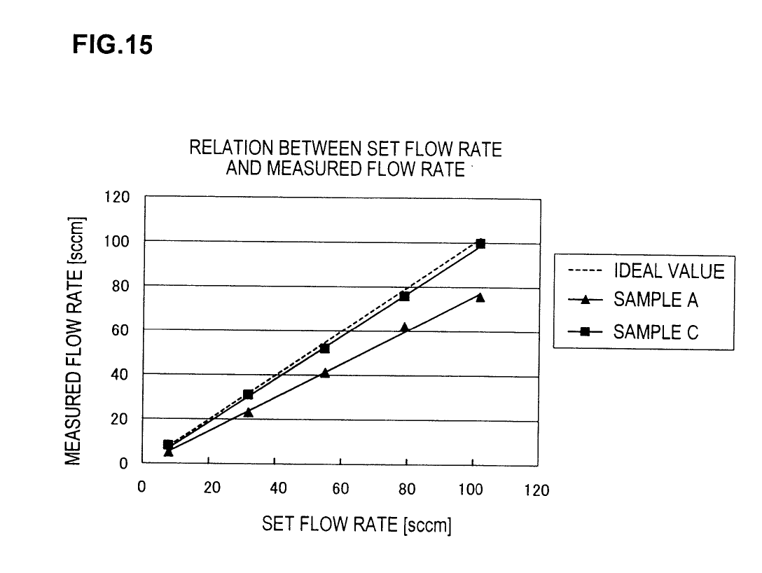

A graph showing experimental results regarding Sample C of Experiment 2.

[FIG. 15]

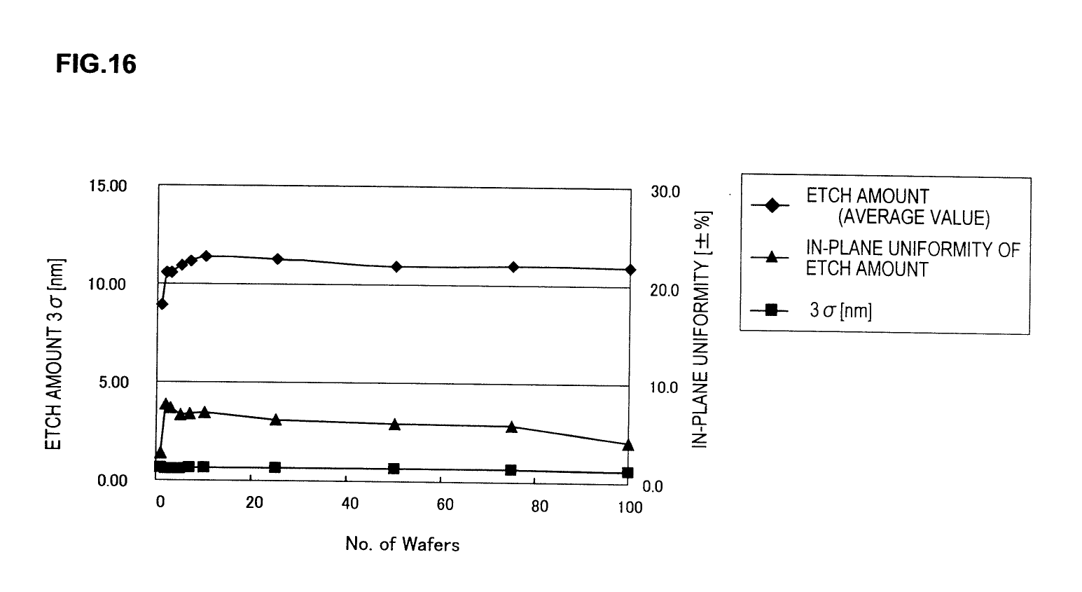

A graph showing experimental results of Experiment 3.

[FIG. 16]

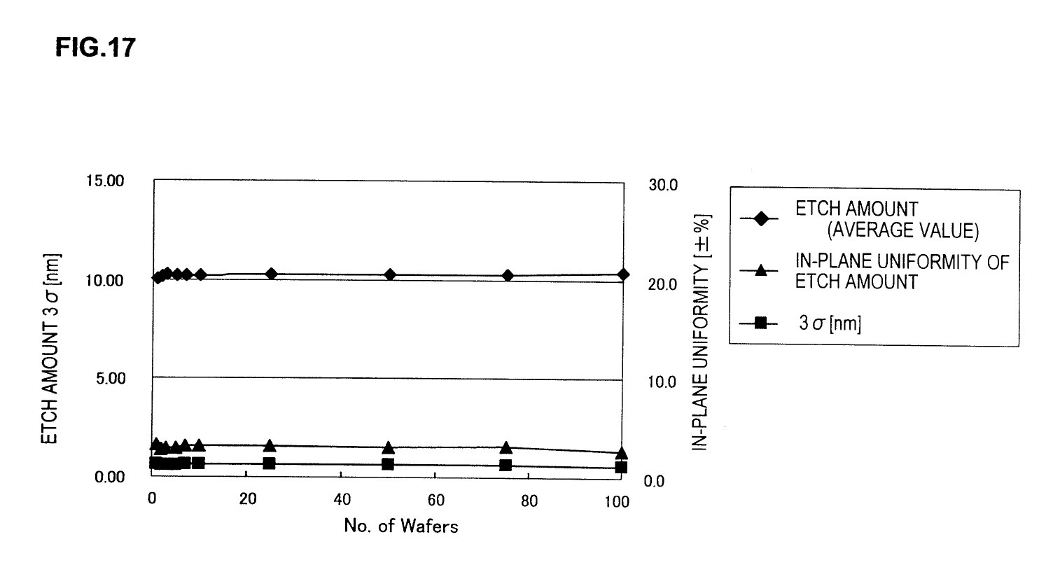

A graph showing experimental results regarding Sample A of Experiment 4.

[FIG. 17]

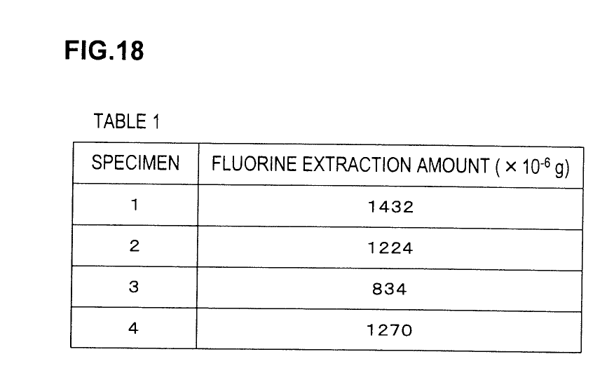

A graph showing experimental results regarding Sample C of Experiment 4.

[FIG. 18]

Table 1 comparing adsorption amounts of hydrogen fluoride of Specimen 1 made of hard alumite sulfate, Specimen 2 made of OGF alumite, Specimen 3 made of Al subjected to mirror polishing (OMCP), and Specimen 4 made of cut Al.

### EXPLANATION OF CODES

W wafer
1 processing system
5 COR processing unit
40 chamber
41 processing chamber
51 chamber main body
52 lid
61 hydrogen fluoride gas supply path
62 ammonia gas supply path
85 exhaust path

### BEST MODE FOR CARRYING OUT THE INVENTION

Hereinafter, a preferred embodiment of the present invention will be described. First of all, a configuration of a wafer that is a substrate to be processed by a processing method according to this embodiment will be described. FIG. 1 is a schematic cross-sectional view of a wafer W before etching treatment, showing a part of a front surface (a device forming surface) of the wafer W. The wafer W is a silicon wafer in a thin film form formed, for example, in an almost disc shape and having a structure formed on its front surface, the structure being composed of a Si (silicon) layer 150 that is a base material of the wafer W, an oxide layer (silicon dioxide: SiO₂) 151 used as an interlayer insulating layer, a Poly-Si (polycrystalline silicon) layer 152 used as a gate electrode, and TEOS (tetraethylorthosilicate: Si(OC₂H₅)₄) layers 153 as side walls composed of insulator. The front surface (top surface) of the Si layer 150 is an almost flat surface, and the oxide layer 151 is layered on the Si layer 150 to cover the front surface thereof. The oxide layer 151 is deposited by the thermal CVD reaction, for example, by a diffusion furnace. The Poly-Si layer 152 is formed on the front surface of the oxide layer 151, and the Poly-Si layer 152 has been etched along a predetermined pattern form. The oxide layer 151 has a portion covered by the Poly-Si layer 152 and another portion exposed. The TEOS layers 153 are formed to cover both side surfaces of the Poly-Si layer 152. In the illustrated example, the Poly-Si layer 152 is formed in an elongated prismatic shape having an almost rectangular cross-sectional shape and extended in a direction toward the bask side from the front side in FIG. 1, and the TEOS layers 153 are provided on both the right and left side surfaces of the Poly-Si layer 152 each along a direction toward the bask side from the front side and to cover the Poly-Si layer 152 from its lower edge to its upper edge. The surface of the oxide layer 151 is exposed on both the right and left sides of the Poly-Si layer 152 and the TEOS layers 153.

FIG. 2 shows a state of the wafer W after etching treatment. After the oxide layer 151, the Poly-Si layer 152, the TEOS layers 153 and so on are formed on the Si layer 150 as shown in FIG. 1, the wafer W is subjected to, for example, dry etching. This removes the oxide layer 151 exposed on the right and left sides of the Poly-Si layer 152 and the TEOS layers 153 and a portion of the Si layer 150 covered by the oxide layer 151 on the front surface of the wafer W as shown in FIG. 2. More specifically, on both the right and left sides of the Poly-Si layer 152 and the TEOS layers 153, recessed portions 155 created by the etching are formed respectively. The recessed portions 155 are formed to cave in down to the Si layer 150 from the level of the lower surface of the oxide layer 151, so that the Si layer 150 is brought exposed on the inner surfaces of the recessed portions 155. Since the Si layer 150 is likely to be oxidized, natural oxide films (silicon dioxide: SiO₂) 156 are formed on the inner surfaces of the recessed portions 155 when oxygen in the air adheres to the front surface of the Si layer 150 exposed in the recessed portions 155.

Next, a processing system performing COR processing and PHT (Post Heat Treatment) processing on the wafer W after etching will be described. Note that the COR processing is processing of supplying a gas containing halogen element and a basic gas, as a processing gas, to the wafer to thereby cause the natural oxide film adhering to the wafer W to chemically react with gas molecules of the processing gas to form a reaction product. The gas containing halogen element is, for example, a hydrogen fluoride gas, and the basic gas is, for example, an ammonium gas. In this case, a reaction product mainly containing ammonium fluosilicate is produced. The PHT processing is processing of heating the wafer which has been subjected to the COR processing to evaporate the reaction product by the COR processing.

A processing system 1 shown in FIG. 3 comprises a transfer-in/out section 2 for transferring-in/out the wafer W to/from the processing system 1, two load lock chambers 3 provided adjacent to the transfer-in/out section 2, PHT processing units 4 provided adjacent to the load lock chambers 3 respectively and performing the PHT processing on the wafer W, and COR processing units 5 as substrate processing apparatuses (vacuum processing apparatuses) according to this embodiment, provided adjacent to the PHT processing units 4 respectively and performing COR processing on the wafer W. The PHT processing unit 4 and the COR processing unit 5 connected to each of the load lock chambers 3 respectively are arranged in a straight line in this order from the load lock chamber 3 side.

The transfer-in/out chamber 3 has a transfer chamber 12 in which a first wafer transfer mechanism 11 transferring the wafer W, for example, in an almost disc shape. The wafer transfer mechanism 11 has two transfer arms 11a and 11b substantially horizontally holding the wafer W. Beside the transfer chamber 12, for example, three mounting tables 13 are provided on which carriers C capable of housing a plurality of arranged wafers W are mounted. An orienter 14 is further installed which rotates the wafer W to optically obtain its eccentricity and align the wafer W.

In the transfer-in/out section 2, the wafer W is held by the transfer arms 11a and 11b, and rotated and moved straight in an almost horizontal plane and raised and lowered by drive of the wafer transfer unit 11, and is thereby transferred to a desired position. The transfer arms 11a and 11b are moved forward and backward with respect to the carrier C on a mounting table 10, the orienter 14, and the load lock chamber 3, whereby the wafer W is transferred in/out.

Each of the load lock chambers 3 is coupled to the transfer chamber 12 with a gate valve 16 being provided between the load lock chambers 3 and the transfer chamber 12. In each of the load lock chambers 3, a second wafer transfer mechanism 17 transferring the wafer W is provided. The wafer transfer mechanism 17 has a transfer arm 17a horizontally holding the wafer W. Further, the load lock chamber 3 can be evacuated.

In the load lock chamber 3, the wafer W is transferred by being held by the transfer arm 17a, and rotated and moved straight in an almost horizontal plane and raised and lowered by drive of the wafer transfer mechanism 17. The transfer arm 17a is moved forward and backward with respect to the PHT processing unit 4 which is connected to each of the load lock chambers 3 in cascade, whereby the wafer W is transferred into/out of the PHT processing unit 4. Further, the transfer arm 17a is moved forward and backward to/form the COR processing unit 5 via the PHT processing unit 4, whereby the wafer W is transferred in/out the COR processing unit 4.

The PHT processing unit 4 comprises a processing chamber (processing space) 21 of an enclosed structure for housing the wafer W therein. Though not shown, a transfer port is provided for transferring-in/out the wafer W to/from the processing chamber 21, and a gate valve 22 is provided for opening/closing the transfer port. The processing chamber 21 is coupled to the load lock chamber 3 with the gate valve 22 being provided between the processing chamber 21 and the load lock chamber 3.

As shown in FIG. 4, a mounting table 23 on which the wafer W is almost horizontally mounted is provided in the processing chamber 21 of the PHT processing unit 4. A supply mechanism 26 including a supply path 25 which supplies, for example, an inert gas such a heated nitrogen gas (N2) into the processing chamber 21 and an exhaust mechanism 28 including an exhaust path which exhausts the processing chamber 21 are further provided. The supply path 25 is connected to a supply source 30 of the nitrogen gas. The supply path 25 is further provided with a flow rate adjusting valve 31 which is capable of performing opening/closing operation of the supply path 25 and adjusting the supply flow rate of the nitrogen gas. The exhaust path 27 is provided with an opening/closing valve 32 and an exhaust pump 33 for forcibly exhausting gas.

As shown in FIG. 5 and FIG. 6, the COR processing unit 5 includes a chamber 40 of an enclosed structure, and the inside of the chamber 40 forms a processing chamber (processing space) 41 in which the wafer W is housed. Inside the chamber 40, a mounting table 42 in provided on which the wafer W is mounted in an almost horizontal state. The COR processing unit 5 further includes a supply mechanism 43 which supplies a gas into the processing chamber 41 and an exhaust mechanism 44 which exhausts the processing chamber 41.

The chamber 40 is composed of a chamber main body 51 and a lid 52. The chamber main body 51 includes a bottom portion 51a and a side wall portion 51b in an almost cylindrical shape. The lower portion of the side wall portion 51b is closed by the bottom portion 51a, and the upper portion of the side wall portion 51b forms an opening. The upper opening is closed by the lid 52.

As shown in FIG. 6, the side wall portion 51b is provided with a transfer port 53 for transferring the wafer W into/out of the processing chamber 41, and a gate valve 54 is provided as an opening/closing mechanism which opens/closes the transfer port 53. The processing chamber 41 is coupled to the processing chamber 21 with the gate valve 54 being provided between the processing chamber 41 and the processing chamber 21 of the PHT processing unit 4.

The lid 52 includes a lid main body 52a and a shower head 52b for discharging the processing gas. The shower head 52b is attached to the lower portion of the lid main body 52a, and the lower surface of the shower head 52b forms an inner surface (lower surface) of the lid 52. Further, the shower head 52b constitutes a ceiling portion of the chamber 40, and is thus placed above the mounting table 42 and configured to supply various kinds of gasses from above onto the wafer W on the mounting table 42. A plurality of discharge ports 52c for discharging gas are opened in the entire lower surface of the shower head 52b.

The mounting table 42 forms an almost circle in plan view and is fixed to the bottom portion 51a. Inside the mounting table 42, a temperature regulator 55 is provided for regulating the temperature of the mounting table 42. The temperature regulator 55 includes a pipe capable of circulating liquid (for example, water) for temperature regulation, so that heat exchange with the liquid flowing in the pipe regulates the temperature of the mounting table 42 to adjust the temperature of the wafer W on the mounting table 42.

As shown in FIG. 5, the supply mechanism 43 includes a hydrogen fluoride gas supply path 61 for supplying hydrogen fluoride gas (HF) as the processing gas containing halogen element to the above-described shower head 52b and the processing chamber 41, an ammonia gas supply path 62 for supplying ammonia gas (NH₃) as the basic gas to the processing chamber 41, an argon gas supply path 63 for supplying argon gas (Ar) as the inert gas to the processing chamber 41, and a nitrogen gas supply path 64 for supplying nitrogen gas (N₂) as the inert gas to the processing chamber 41. The hydrogen fluoride gas supply path 61, the ammonia gas supply path 62, the argon gas supply path 63 and the nitrogen gas supply path 64 are connected to the shower head 52b so that the hydrogen fluoride gas, ammonia gas, argon gas, and nitrogen gas are diffusively discharged in the processing chamber 41 via the shower head 52b.

The hydrogen fluoride gas supply path 61 is connected to a hydrogen fluoride supply source 71. The hydrogen fluoride gas supply path 61 is further provided with a flow rate adjusting valve 72 capable of performing opening/closing operation of the hydrogen fluoride gas supply path 61 and adjusting the supply flow rate of the hydrogen fluoride gas. The ammonia gas supply path 62 is connected to an ammonia gas supply source 73. The ammonia gas supply path 62 is further provided with a flow rate adjusting valve 74 capable of performing opening/closing operation of the ammonia gas supply path 62 and adjusting the supply flow rate of the ammonia gas. The argon gas supply path 63 is connected to an argon gas supply source 75. The argon gas supply path 63 is further provided with a flow rate adjusting valve 76 capable of performing opening/closing operation of the argon gas supply path 63 and adjusting the supply flow rate of the argon gas. The nitrogen gas supply path 64 is connected to a nitrogen gas supply source 77. The nitrogen gas supply path 64 is further provided with a flow rate adjusting valve 78 capable of performing opening/closing operation of the nitrogen gas supply path 64 and adjusting the supply flow rate of the nitrogen gas.

The exhaust mechanism 44 includes an exhaust path 85 provided with an opening/closing valve 82 and an exhaust pump 83 for forcibly exhausting gas. The end opening of the exhaust path 85 is open in the bottom portion 51a.

As the material of various kinds of components such as the chamber 40, the mounting table 42, and so on constituting the COR processing unit 5, Al (aluminum) is used. Though the inner surface of the chamber 40 (the inner surface of the chamber main body 51, the lower surface of the shower head 52b and so on) is usually subjected to surface oxidation treatment, the inner surface has not been subjected to surface oxidation treatment in this embodiment so that solid Al is kept exposed as it is. In other words, there is no oxide coating which is likely to adsorb hydrogen fluoride. In this case, the hydrogen fluoride gas supplied into the chamber 40 can be prevented from staying adhering on the inner surface of the chamber 40. Note that the oxide coating formed by the surface oxidation treatment is in a porous state in which an infinite number of pores exist in the surface, and thus it is conceivable that hydrogen fluoride is likely to be adsorbed by the oxide coating because components of hydrogen fluoride stay adhering to the pores. It is believed that, in contrast to the above, the surface of solid Al is a smooth surface, and therefore hydrogen fluoride is not likely to stay thereon. Such stay of hydrogen fluoride can be further suppressed by decreasing a surface roughness Ra of the inner surface of the chamber 40 (the inner surface of a portion composed of Al such as the inner surface of the chamber main body 51, the lower surface of the shower head 52b and so on) where Al is exposed as it is. In this case, the surface roughness Ra is defined by a calculated average roughness Ra (Ra=(1/L)∫₀^{L}|f(x)|dx) of the inner surface of the chamber 40 (the inner surface of a portion composed of Al). Reducing the surface roughness Ra to, for example, 6.4 μm or less, more preferably 1 μm or less can more surely prevent stay of hydrogen fluoride.

On the other hand, the surface of Al constituting the mounting table 42 can receive friction or impact due to mounting of the wafer W thereon, and therefore is preferably subjected to surface oxidation treatment. More specifically, the surface of the mounting table 42 is forcibly oxidized to form an oxidation coating (Al₂O₃) so that the oxide coating covers the outer surface of Al. This configuration can improve the hardness, the corrosion resistance, and the durability of the outer surface of the mounting table 42 to protect Al constituting the mounting table 42 from corrosion, impact and so on.

Next, a processing method of the wafer W in the processing system 1 configured as described above will be described. As shown in FIG. 1, the wafer W having the Si layer 150, the oxide layer 151, the Poly-Si layer 152, and the TEOS layer 153 is subjected to etching treatment by a dry etching unit or the like, whereby the recessed portions where the Si layer 150 is exposed are formed as shown in FIG. 2. The wafer W after subjected to the dry etching treatment is housed in the carrier C and transferred into the processing system 1.

In the processing system 1, as shown in FIG. 3, the carrier C housing a plurality of wafers W is mounted on the mounting table 13, and one wafer W is taken out from the carrier C by the wafer transfer mechanism 11 and transferred into the load lock chamber 3. After the wafer W is transferred in the load lock chamber 3, the load lock chamber 3 is hermetically closed and reduced in pressure. Thereafter, the gate valves 22 and 54 are opened, whereby the load lock chamber 3 is brought into communication with the processing chamber 21 of the PHT processing unit 4 and the processing chamber 41 of the COR processing unit 5 which are reduced in pressure as compared to the atmospheric pressure. The wafer W is transferred out of the load lock chamber 3 by the wafer transfer mechanism 17 and moved straight to pass though the transfer port (not shown) of the processing chamber 21, the processing chamber 21, and the transfer port 53, and is transferred into the processing chamber 41.

In the processing chamber 41, the wafer W is delivered from the transfer arm 17a of the wafer transfer mechanism 17 to the mounting table 42 with its front surface (device formation surface) facing upward. After the wafer W is transferred in, the transfer port 53 is closed, whereby the processing chamber 41 is hermetically closed.

After the processing chamber 41 is hermetically closed, the ammonia gas, argon gas, and nitrogen gas are supplied from the ammonia gas supply path 62, the argon gas supply path 63, and the nitrogen gas supply path 64, respectively. The temperature of the wafer W is adjusted by the temperature regulator 55 to a predetermined target value (for example, about 25° C.).

Thereafter, the hydrogen fluoride gas is supplied from the hydrogen fluoride gas supply path 61 into the processing chamber 41. Since the ammonia gas has been supplied into the processing chamber 41 in advance, the hydrogen fluoride gas is supplied to thereby bring the atmosphere in the processing chamber 41 into a processing atmosphere containing the hydrogen fluoride gas and the ammonia gas, and the COR processing is started on the wafer W.

Note that the pressure in the processing chamber 41 is reduced to be stabilized at a predetermined pressure before supply of the hydrogen fluoride gas, thereby making it easy to stabilize the pressure of the processing atmosphere and possible to improve the uniformity of the concentrations of the hydrogen fluoride gas and the ammonia gas in the processing atmosphere. Accordingly, processing unevenness of the wafer W can be prevented. Further, though the hydrogen fluoride gas is likely to be liquefied and adhere to the inner surface of the chamber 40 and so on, occurrence of such a problem can be prevented by supplying the hydrogen fluoride gas immediately before the COR processing.

The natural oxide films 156 existing on the surfaces of the recessed portions 155 of the wafer W chemically react with molecules of the hydrogen fluoride gas and molecules of the ammonia gas by the processing atmosphere in the reduced state in the processing chamber 41 to change into reaction products (see FIG. 7). During the COR processing, the atmosphere in the processing chamber 41 is kept at a fixed pressure which is reduced in pressure to be lower than the atmospheric pressure (for example, on the order of about 0.1 Torr (about 13.3 Pa)).

As the reaction products, ammonium fluosilicate, water and so on are produced, and the produced water does not diffuse from the front surface of the wafer W but is confined in the reaction products (the natural oxide films 156 changed into the reaction products) and kept on the front surface of the wafer W. Note that the inner surface of the chamber 40 has not been subjected to the surface oxidation treatment and Al is therefore exposed there, but the water produced by the reaction never contacts the inner surface of the chamber 40 because it does not diffuse from the reaction products (the natural oxide films 156 changed into the reaction products). Accordingly, Al constituting the inner surface of the chamber 40 is never corroded by the water, even if Al is exposed.

Further, since substantially no porous oxide coating which is likely to adsorb hydrogen fluoride exists on the inner surface of the chamber 40, the hydrogen fluoride in the processing atmosphere in the processing chamber 41 can be prevented from being adsorbed by the inner surface of the chamber 40. Further, hydrogen fluoride is not likely to be accumulated in the inner surface of the chamber 40 and is therefore never released from the inner surface of the chamber 40 into the processing atmosphere. Accordingly, it is possible to prevent increases in concentration and pressure of the hydrogen fluoride gas in the processing atmosphere. In other words, the concentration and pressure of the hydrogen fluoride gas in the processing chamber 41 can be prevented from increasing and decreasing or becoming uneven, thereby preferably stabilizing the processing atmosphere. Accordingly, occurrence of processing unevenness of the wafer W can be prevented, leading to sure processing of the wafer W.

After completion of the COR processing, the processing chamber 41 is forcibly exhausted and thereby reduced in pressure. This forcibly exhausts the hydrogen fluoride gas and the ammonia gas from the processing chamber 41. In this event, the inner surface of the chamber 40 is composed of solid Al to make the hydrogen fluoride difficult to stay on the inner surface of the chamber 40, thus ensuring that the components of the hydrogen fluoride are smoothly and quickly exhausted from the processing chamber 41. Accordingly, the hydrogen fluoride can be surely prevented from leaking to the outside of the chamber 40, leading to safety. Further, the time required for forced exhaust after the COR processing can be short to improve throughput.

After completion of the forced exhaust, the transfer port 53 is opened, and the wafer W is transferred out by the wafer transfer mechanism 17 from the processing chamber 41 and transferred into the processing chamber 21 of the PHT processing unit 4.

In the PHT processing unit 4, the wafer W is mounted in the processing chamber 21 with its front surface facing upward. After the wafer W is transferred in, the processing chamber 21 is hermetically closed, and the PHT processing is started on the wafer W. In the PHT processing, while the processing chamber 21 is being exhausted, a heating gas at a high temperature is supplied into the processing chamber 21 to increase the temperature in the processing chamber 21. This heats and evaporates the reaction products (the natural oxide films 156 changed into the reaction products) produced by the above-described COR processing, so that the reaction products are removed from the inner surfaces of the recessed portions 155 to expose the surface of the Si layer 150 (see FIG. 8). Thus, the PHT processing performed after the COR processing can dry-clean the wafer W in which the natural oxide films 156 can be removed from the surface of the Si layer 150 by dry-etching.

After completion of the PHT processing, the supply of the heating gas is stopped, and the transfer port of the PHT processing unit 4 is opened. Thereafter, the wafer W is transferred by the wafer transfer mechanism 17 from the processing chamber 21 and returned into the load lock chamber 3.

After the load lock chamber 3 is hermetically closed, the load lock chamber 3 is brought into communication with the transfer chamber 12. The wafer W is then transferred by the wafer transfer mechanism 11 from the load lock chamber 3 and returned back into the carrier C on the mounting table 13. Thus, a series of processes in the processing system 1 is completed.

Note that the wafer W for which the COR processing and the PHT processing have been finished in the processing system 1 is transferred into an epitaxial growth unit in another processing system and subjected to SiGe deposition processing. In the deposition processing, a reactive gas supplied into a processing chamber 34 reacts with the Si layer 150 exposed in the recessed portions 155 of the wafer W, whereby SiGe layers 157 epitaxially grow in the recessed portions 155 (see FIG. 9). Since the natural oxide films 156 have been removed by the above-described COR processing and PHT processing from the surface of the Si layer 150 exposed in the recessed portions 155, the SiGe layers 157 can be preferably grown using the surface of the Si layer 150 as a base. The SiGe layers 157 are thus formed in the recessed portions 155 on both sides respectively, whereby a portion of the Si layer 150 sandwiched between the SiGe layers 157 receives a compression stress from both sides. More specifically, below the Poly-Si layer 152 and the oxide layer 151, a strained Si layer 158 having compression strain is formed at a portion sandwiched between the SiGe layers 157.

With the OCR processing unit 5 of the processing system 1, oxide coating by the surface oxidation treatment is not formed on the inner surface of the chamber 40, thus preventing hydrogen fluoride from staying adhering to the inner surface of the chamber 40. In this case, the surface roughness Ra of the inner surface of the chamber 40 (a portion which has not been subjected to the surface oxidation treatment but is kept Al as it is) can be reduced to, for example, 6.4 μm or less, more preferably 1 μm or less, thereby more surely suppressing stay of the hydrogen fluoride. This can stabilize the concentration and pressure of the hydrogen fluoride in the chamber 41 to target values to prevent processing unevenness of the wafer W. Accordingly, the reliability of the processing of the wafer W can be improved. Further, the hydrogen fluoride does not stay on the inner surface of the chamber 40 but can be quickly exhausted from the processing chamber 41, resulting in improved throughput. Further, the hydrogen fluoride can be surely exhausted, leading to increased safety.

A preferred embodiment of the present invention has been described, and the present invention is not limited to the embodiment. It should be understood that various changes and modifications within the scope of the technical spirit as set forth in claims are readily apparent to those skilled in the art, and those should also be covered by the technical scope of the present invention.

Though the COR processing unit 5 has been illustrated, for example, as the substrate processing apparatus for supplying hydrogen fluoride to process the substrate in the above embodiment, the present invention is not limited to that apparatus but is also applicable to another substrate processing apparatus, such as a substrate processing apparatus for performing etching treatment of an oxide film and the like for the substrate. Besides, the substrate is not limited to the semiconductor wafer but may be, for example, glass for an LCD substrate, a CD substrate, a printed substrate, and a ceramic substrate.

The portion which is not subjected to the surface oxidation treatment but is kept solid Al as it is in the chamber 40 is not limited to the location shown in the above-described embodiment. For example, the inner surface of the gate valve 54 (the surface facing the inner surface of the chamber 40) may be kept solid Al. Besides, only the lower surface of the lid 52 (the lower surface of the shower head 52b) may be kept solid Al and the inner surface of the chamber main body 51 may be subjected to the surface oxidation treatment. Alternatively, the inner surface of the chamber main body 51 may be kept solid Al and the lower surface of the lid 52 may be subjected to the surface oxidation treatment. This case is also effective because the adsorption amount of hydrogen fluoride can be reduced as compared to the case in which the entire inner surface of the chamber 40 is subjected to the surface oxidation treatment.

Though the material constituting the chamber 40 is Al, it may be Al alloy containing Al as a main component. It can be believed that the surface of the solid Al alloy which is not subjected to the surface oxidation treatment is a smooth surface which makes it difficult for hydrogen fluoride to stay thereon. Accordingly, also in this case, the adsorption amount of hydrogen fluoride can be reduced by keeping a part or whole of the inner surface of the chamber 40 the solid Al alloy without performing the surface oxidation treatment thereon.

The kinds of gasses to be supplied into the processing chamber 41 other than hydrogen fluoride are not limited to the combination described in the above embodiment. For example, the inert gas to be supplied into the processing chamber 41 may contain only argon gas. Further, the inert gas may be another gas, for example, either helium gas (He) or xenon gas (Xe), or a mixture of two or more kinds of gasses out of argon gas, nitrogen gas, helium gas, and xenon gas.

Moreover, the structure of the processing system 1 is not limited to that described in the above embodiment. The processing system may be one including an epitaxial growth unit in addition to the COR processing unit and the PHT processing unit. For example, a configuration is also employable in which, as in a processing system 90 shown in FIG. 10, a common transfer chamber 92 including a wafer transfer mechanism 91 is coupled to a transfer chamber 12 via load lock chambers 93, and a COR processing unit 95, a PHT processing unit 96, epitaxial growth units 97 are arranged around the common transfer chamber 92. This processing system 90 is configured such that the wafer W is transferred by the wafer transfer mechanism 91 into/out of the load lock chamber 92, the COR processing unit 95, the PHT processing unit 96, and the epitaxial growth units 97. The common transfer chamber 92 can be evacuated. More specifically, keeping the common transfer chamber 92 evacuated allows the wafer W transferred out of the PHT processing unit 96 to be transferred into the epitaxial growth unit 97 without contact with oxygen in the atmospheric air. Accordingly, it is possible to prevent a natural oxide film from adhering again to the wafer W after the PHT processing and preferably perform epitaxial growth. Furthermore, the present invention is also applicable, for example, to a processing system 106 in which six processing units 100 to 105 around a common transfer chamber 99 as shown in FIG. 11. Any number and arrangement of processing units provided in the processing system may be employed.

### EXAMPLES

### (Experiment 1)

The present inventors carried out experiments, on later-described three Samples A, B and C of the chamber 40, to investigate changes in pressure in the processing chamber 41 when hydrogen fluoride gas was supplied. Sample A is a chamber 40 made of Al having an entire inner surface subjected to surface oxidation treatment, and the chamber 40 is unused. Sample B is a chamber 40 having an inner surface of a chamber main body 51 subjected to surface oxidation treatment and a lower surface of a lid 52 (a lower surface of a shower head 52b) kept solid Al, and the chamber 40 is unused. Sample C is a chamber 40 having an entire inner surface made of solid Al, and the chamber 40 is unused. In each of Samples as described above, hydrogen fluoride gas was supplied to the processing chamber 41 while adjusting the pressure in the processing chamber 41 to bring the pressure in the processing chamber 41 to about 5 Ton (about 6.67×102 Pa), the supply of the hydrogen fluoride gas was stopped, the inside of the processing chamber 41 was kept hermetically closed and left standing for several minutes, and the change in pressure in the processing chamber 41 was then measured. The results are shown in a graph in FIG. 12. As shown in FIG. 12, the results show that the amount of reduced pressure gets smaller in the order of Samples A, B and C. It is conceivable that this is because the adsorption amount of hydrogen fluoride in the processing chamber 41 adsorbed to the inner surface of the chamber 40 and the like gets smaller in this order. The results show that a part or whole of the inner surface of the chamber 40 is kept solid Al to enable effective prevention of the adsorption of hydrogen fluoride and prevention of the reduction in pressure in the processing chamber 41. Further, it is also shown that as the portion made of solid Al is increased, the adsorption amount of hydrogen fluoride can be reduced to prevent a reduction in pressure in the processing chamber 41.

### (Experiment 2)

Experiment 2 was carried out, on the above-described two kinds of Samples A and C, to compare changes in pressure in the processing chamber 41 when hydrogen fluoride gas was supplied into the processing chamber 41 and the pressure reduction was then performed. Specifically, first of all, while hydrogen fluoride gas was being supplied at a fixed flow rate (about 80 sccm (about 1.35×10⁻¹ m³/s)) into the processing chamber 41, forced exhaust was performed at a fixed exhaust rate to bring the pressure in the processing chamber 41 to a predetermined value (about 2.5 mTorr (about 0.33 Pa)). In this state, the supply of the hydrogen fluoride gas was stopped, and only the forced exhaust was continued to thereby reduce the pressure in the processing chamber 41. Then, the change in pressure in the processing chamber 41 in this event was measured. The results are shown in graphs in FIG. 13 and FIG. 14. As shown in FIG. 13, in Sample A, it took about 60 seconds from start of the exhaust to the time when the pressure in the processing chamber 41 was reduced to about 0 mTorr. In contrast, as shown in FIG. 14, in Sample C, the time required from start of the exhaust to the time when the pressure in the processing chamber 41 was reduced to about 0 mTorr was about 15 seconds, that is about ¼ the time required in Sample A. A conceivable reason why the reduction in pressure in Sample A took a long time is that the hydrogen fluoride adsorbed to the oxide coating in the chamber 40 evaporated again during the exhaust and was released in the processing chamber 41 to increase the amount of gas in the processing chamber 41 to thereby inhibit the reduction in pressure. On the other hand, it is conceivable that, in Sample C, hydrogen fluoride was not adsorbed to the inner surface of the chamber 40, so that no hydrogen fluoride was released from the inner surface of the chamber 40 during the exhaust to allow rapid exhaust. Accordingly, it was confirmed that, by keeping the inner surface of the chamber 40 solid Al to prevent adsorption of hydrogen fluoride, the exhaust of processing chamber 41 can be efficiently performed and the time required for the exhaust can substantially be reduced.

### (Experiment 3)

Experiment 3 was carried out, on the above-described two kinds of Samples A and C, to investigate the actual supply flow rate (measured flow rate) of hydrogen fluoride gas measured in the processing chamber 41 when the hydrogen fluoride gas was supplied at a predetermined set flow rate into the processing chamber 41, for various set flow rates. The results of this Experiment 3 are shown in a graph in FIG. 15. As shown in FIG. 15, Sample C was smaller in difference between the set value (ideal value) and the measured value than Sample A. It is conceivable that this is because a part of the hydrogen fluoride gas supplied into the processing chamber 41 was adsorbed into the oxide coating to decrease the volume of the hydrogen fluoride gas actually existing in the atmosphere in the processing chamber 41. It can be said from the above results that Sample C can prevent adsorption of hydrogen fluoride and accurately and efficiently adjust the concentration and pressure of the hydrogen fluoride in the processing chamber 41 at a set supply flow rate.

### (Experiment 4)

The present inventors carried out Experiment 4 on two kinds of Samples A and C to investigate the amount of etching performed on each wafer W and the uniformity of etching when 100 wafers W were successively processed. The etch amounts were measured at a plurality of locations on the wafer W respectively for each wafer, and an average value [nm] of the etch amounts, an in-plane uniformity of the etch amounts (Etch Amount Uniformity) (deviations of the etch amounts within the wafer W) [±%], and 3 σ[nm] (σ: standard deviation) were calculated. Note that the target value of the etch amount was set to 10 nm. The results of Experiment 4 are shown in graphs in FIG. 16 and FIG. 17. As is clear from comparison between FIG. 16 and FIG. 17, Sample C was able to more closely achieve the target etch amount and had less variation in each wafer W and therefore better uniformity than Sample A. Accordingly, it was confirmed that the reliability of the etching treatment was higher. Note that in Sample A, the etch amount in the first wafer W is less than the target value, and it is believed that this is because a part of the hydrogen fluoride gas supplied into the processing chamber 41 was adsorbed by the oxide coating, whereby the concentration and pressure of the hydrogen fluoride in the processing chamber 41 were decreased, leading to lowered processing performance. Further, in Sample A, the etch amounts in the second and subsequent wafers W are considerably greater than the target value, and it is believed that this is because the adsorption performance of hydrogen fluoride in the oxide coating had already become saturated, that is, adsorption was not performed any longer during processing of the second and subsequent wafers W, and the hydrogen fluoride accumulated in the oxide coating was released from the oxide coating, whereby the concentration and pressure in the processing chamber 41 increased to excessively improve the processing performance of etching. In contrast, in Sample C, the etch amount in the first wafer W was almost the target value, and the etch amounts in the second and subsequent wafers W were able to substantially reach the target. It is conceivable that this is because no oxide coating had been formed on the inner surface of the chamber 40, and therefore adsorption and release of hydrogen fluoride were not performed, so that the concentration and pressure of the hydrogen fluoride in the processing chamber 41 were maintained almost at the target values to stabilize the treatment performance of etching. The above results show that forming no oxide coating on the inner surface of the chamber 40 can stabilize the concentration and pressure of the hydrogen fluoride in the processing chamber 41 to thereby preferably control the treatment performance of etching.

### (Experiment 5)

The adsorption amounts of hydro fluoride were compared for Specimen 1 made of hard alumite sulfate, Specimen 2 made of OGF alumite, and Specimens 3 and 4 made of Al (solid Al). Note that OGF alumite of Specimen 2 is a material having a very small amount of gas released from the coating which has been subjected to OUT GAS FREE (OGF) surface treatment for high vacuum. “OGF” is a registered trademark of Mitsubishi Aluminum Co., Ltd. The surface of Specimen 3 made of Al was subjected to mirror polishing (OMCP) so that the surface roughness Ra was set to about 0.1 μm to about 1.0 μm. On the other hand, the surface of Specimen 4 made of Al was a cut Al (Bare) without being subjected to special surface treatment. The surface roughness Ra of the Specimen 4 is about 3.2 μm to about 6.4 μm. Each of the Specimens 1 to 4 was placed under an atmosphere of hydrogen fluoride gas, and the extraction amount of fluorine per unit area in each of Specimens 1 to 4 was measured by ion chromatography. As a result, Table 1 shown in FIG. 18 was obtained.

It is believed that the fluorine extraction amounts measured from Specimens 1 to 4 are proportional to the adsorption amounts of hydrogen fluoride for Specimens 1 to 4. Comparison between Specimen 1 and Specimen 4 shows that the cut Al (Specimen 4), even without being subjected to special surface treatment, has the adsorption amount of hydrogen fluoride lower than that of hard alumite sulfate (Specimen 1). Note that the cut Al (Specimen 4) can prevent the reduction in pressure in the processing chamber (Experiment 1), considerably reduce the exhaust time (Experiment 2), and accurately adjust the supply flow amount (Experiment 3), and is excellent in etching uniformity (Experiment 4), as compared to hard alumite sulfate (Specimen 1). Further, comparison between Specimen 2 and Specimen 4 shows that the cut Al (Specimen 4), even without being subjected to special surface treatment, has the adsorption amount of hydrogen fluoride as low as that of OGF alumite (Specimen 2) which has been subjected to OGF surface treatment in order to reduce the gas release amount. Further, comparison between Specimen 3 and Specimen 4 shows that Al (Specimen 3) having a surface roughness Ra of about 0.1 μm to about 1.0 μm which has been subjected to mirror polishing has an adsorption amount of hydrogen fluoride lower than that of the cut Al (Specimen 4) having a surface roughness Ra of about 3.2 μm to about 6.4 μm which has not been subjected to mirror polishing, so that the adsorption amount of hydrogen fluoride is inversely proportional to the surface roughness Ra.

### INDUSTRIAL APPLICABILITY

The present invention is applicable to a substrate processing apparatus.

1. A method for processing a substrate in a chamber, comprising:
supplying a hydrogen fluoride gas into said chamber,
wherein a part or whole of an inner surface of said chamber is formed of Al or Al alloy which has not been subjected to surface oxidation treatment.

2. The substrate processing method as set forth in claim 1, further comprising:
providing said chamber such that it includes a chamber main body and a lid closing an upper opening of said chamber main body, wherein
at least an inner surface of said lid is formed of the Al or Al alloy which has not been subjected to surface oxidation treatment.

3. The substrate processing method as set forth in claim 1, further comprising:
transferring the substrate into/out of said chamber by a transfer port, and opening/closing said transfer port by an opening/closing mechanism, wherein
an inner surface of said opening/closing mechanism facing an inside of said chamber is formed of the Al or Al alloy which has not been subjected to surface oxidation treatment.

4. The substrate processing method as set forth in claim 1, further comprising providing a surface roughness Ra of a portion formed of the Al or Al alloy to be 6.4 μm or less.

5. The substrate processing method as set forth in claim 1, further comprising providing a surface roughness Ra of a portion formed of the Al or Al alloy to be 1 μm or less.

6. The substrate processing method as set forth in claim 1, further comprising supplying an ammonia gas into said chamber is by an ammonia gas supply path.

7. The substrate processing method as set forth in claim 1, further comprising forcibly exhausting said chamber through an exhaust path.

8. The substrate processing method as set forth in claim 1, wherein said processing in said chamber changes silicon dioxide existing on a surface of the substrate into a reaction product capable of vaporizing by heating.
